(19) United States
(12) Patent Application Publication
(10) Pub. No.: US 2011/0290301 A1
(43) Pub. Date: Dec. 1, 2011

(54) SYSTEM FOR GENERATING ELECTRIC ENERGY BY MEANS OF PHOTOVOLTAIC ELEMENTS

(75) Inventors: Philipp Erhart, Krems (AT); Hans Günter Czaloun, Seis (IT)

(73) Assignee: INNOVA PATENT GMBH, WOLFURT (AT)

(21) Appl. No.: 13/145,213

(22) PCT Filed: Jan. 19, 2010
(86) PCT No.: PCT/AT2010/000015

§ 371 Date: Aug. 8, 2011

(30) Foreign Application Priority Data
Jan. 19, 2009 (AT) A 76/2009

(51) Int. Cl. H01L 31/052

(52) U.S. Cl. 136/246

(57) ABSTRACT

A system for generating electric energy uses photovoltaic elements that are disposed on a supporting structure formed, in particular, by supporting cables and adjusting cables or the like. The elements can be pivoted about at least approximately vertically oriented axes, whereby they can track the east-west movement of the sun, and they can be pivoted about at least approximately horizontally oriented axes, whereby they can be adjusted to the altitude of the sun. The photovoltaic elements are attached on several supporting beams, which are oriented at least approximately parallel to each other and approximately horizontally, the supporting beams can be pivoted at one of the two ends thereof on a supporting cable or the like about an at least approximately vertical axis and are mounted rotatably about the longitudinal axes thereof. The supporting beams are coupled at the other end thereof to a pivoting and rotating device, which is formed by at least one supporting and adjusting cable.

The subject matter of the invention relates to a system for generating electrical energy by means of photovoltaic elements, which are located on a supporting framework formed in particular by supporting cables and adjusting cable or the like and which can be pivoted about at least approximately vertically aligned axes as a result of which they can track the east-west movement of the sun, and can furthermore be pivoted about at least approximately horizontally aligned axes, as a result of which they can be adjusted to the solar altitude.

Such a system for generating electrical energy by means of photovoltaic elements is known from WO 2008/064382 A2. In this known system, the individual photovoltaic elements are in the form of rectangular plates, which are formed with spindle journals, which protrude horizontally from both of their ends and are articulated at their free ends on adjusting cables, which are guided over deflection pulleys and are self-contained. The strands of a first one of these two adjusting cables are capable of being moved in a vertical plane about two deflection pulleys aligned in a vertical plane, and the two strands of the second of these two adjusting cables are capable of being moved in a horizontal plane about two deflection pulleys aligned in a horizontal plane, wherein the respectively associated strands can be adjusted with respect to one another. The photovoltaic elements are mounted on the first adjusting cable in such a way as to be capable of being pivoted about vertically aligned axes, as a result of which they can track the east-west movement of the sun in the case of an adjustment of the second adjusting cable. The photovoltaic elements are mounted on the second adjusting cable in such a way that they can pivot about horizontal axes, as a result of which they can track the solar altitude by virtue of an adjustment of the first adjusting cable. Since in this case each photovoltaic element is articulated on two differently aligned adjusting cables and separate drives are provided for all of the adjusting cables, this known system has a very complex structural design.

The subject matter of the invention is therefore based on the object of providing a system for generating electrical energy using a large number of photovoltaic elements which can be adjusted with respect to the respective solar altitude, in which system the disadvantage associated with the known prior art is avoided, said system therefore having a substantially simplified design in comparison with the known structural configurations. This object is achieved according to the invention in that the photovoltaic elements are fixed to a plurality of supporting bars or the like, which are at least approximately parallel to one another and are aligned approximately horizontally, in that the supporting bars or the like, at one of their two ends on a supporting cable or the like, can firstly be pivoted about an at least approximately vertical axis and are secondly mounted rotatably about their longitudinal axis and in that the supporting bars are coupled at their other end to a pivoting and rotating device, which is formed by at least one supporting and adjusting cable.

Preferably, the pivoting and rotating device is formed by a supporting and adjusting cable or the like, which is provided with two strands, which are approximately parallel to one another, it being possible for said supporting and adjusting cable to be moved in the longitudinal direction thereof and for the two strands thereof to be adjusted with respect to one another. Further preferably, transverse struts, which are fixedly connected to the associated ends of the supporting bars or the like, are located between the two strands of the supporting and adjusting cable, said transverse struts being articulated on said strands.

In accordance with a preferred embodiment, at least one of the supporting bars or the like is mounted on a supporting column, supporting post or the like in such a way that it is capable of pivoting and rotating with respect thereto, with furthermore firstly a pivoting device and secondly a rotating device for these supporting bars or the like being provided on the supporting column. Further preferably, the pivoting movements and the rotating movements of the supporting bar, which is mounted on the supporting column, supporting post or the like, can be transferred to the other supporting bar or the like via the longitudinal adjustment of the supporting and adjusting cable, and via the adjustment in the opposite direction of the two strands of the supporting and adjusting cable, which is coupled to this supporting bar.

In accordance with a preferred embodiment of a system according to the invention for generating electrical energy, in each case one supporting column, supporting post or the like is provided at the two ends of the supporting framework, which is formed in particular by supporting and adjusting cables or the like, wherein the supporting bars or the like located there are mounted on said supporting columns, supporting posts or the like pivotably or rotatably, at least one of the two supporting columns, supporting posts or the like is formed with drives for pivoting and rotating the associated supporting bar, and the supporting bars or the line for the photovoltaic elements are mounted at one of their two ends on a first supporting cable in such a way that they can be pivoted about an at least approximately vertical axis and can be rotated about their longitudinal axis and are coupled to one another by means of the supporting and adjusting cable associated with the other ends so as to enable pivoting about at least approximately vertical axes and rotation about its longitudinal axis.

The subject matter of the invention will be explained in more detail below with reference to two exemplary embodiments illustrated in the drawing, in which:

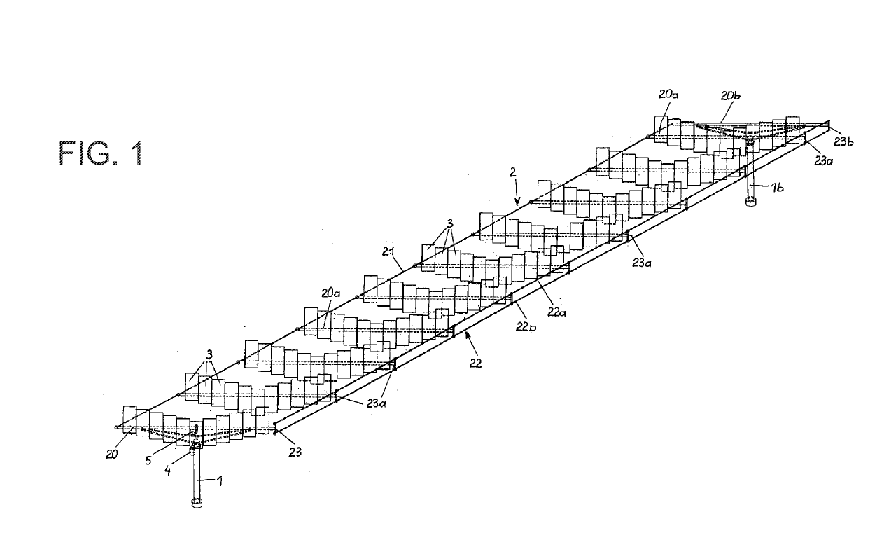

FIG. 1 shows a first exemplary embodiment of a system according to the invention for generating electrical energy by means of photovoltaic elements, in an axonometric illustration,

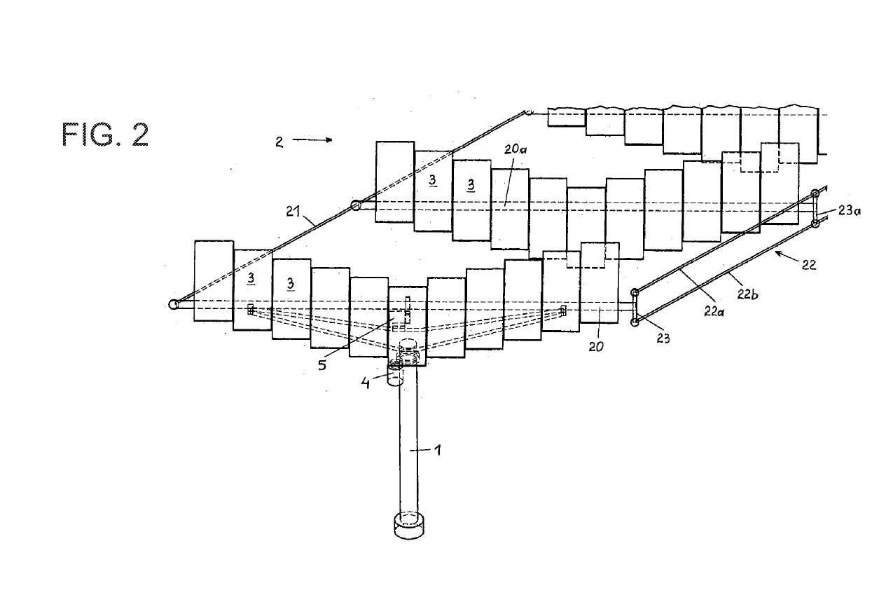

FIG. 2 shows the exemplary embodiment shown in FIG. 1 on an enlarged scale in comparison with FIG. 1 and in a broken-away illustration,

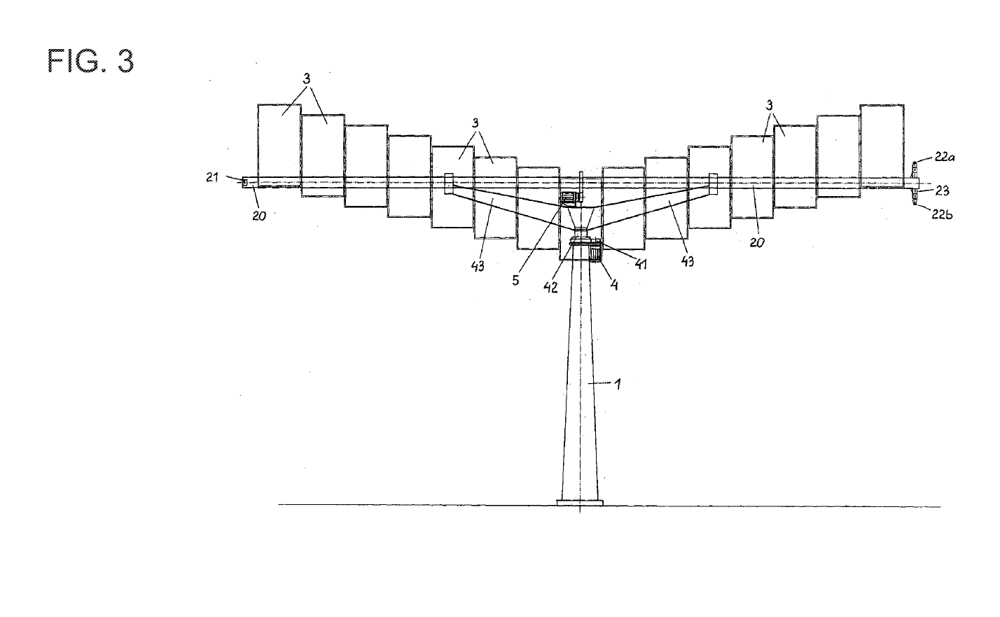

FIG. 3 shows the exemplary embodiment shown in FIG. 1, in a front view,

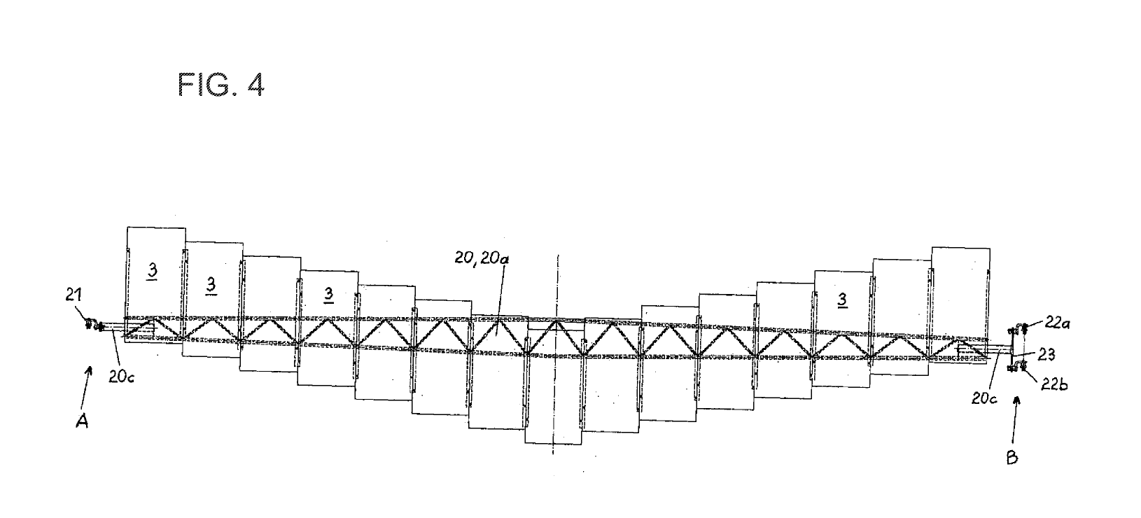

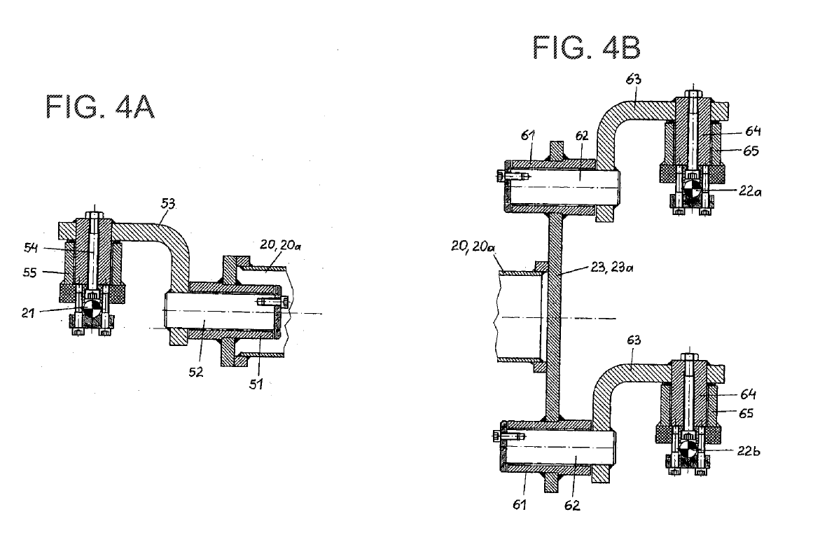

FIG. 4 shows a detail from FIG. 3,

FIG. 4a, FIG. 4b show details A and B of FIG. 4 on an enlarged scale in comparison with said figure and in section,

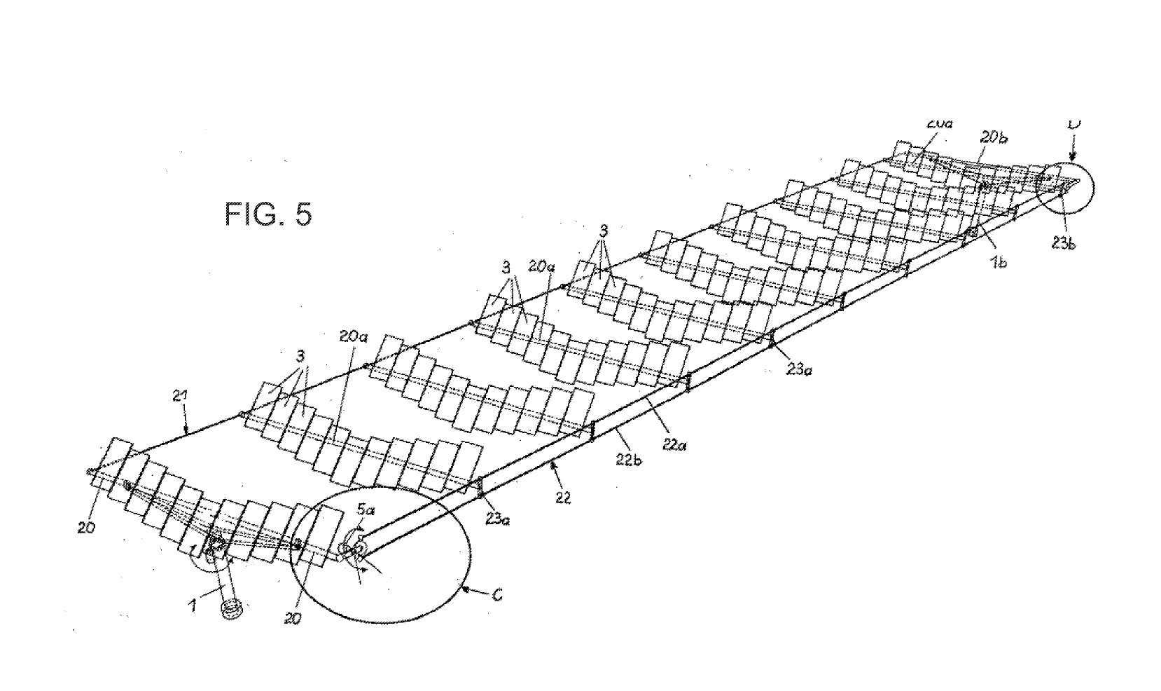

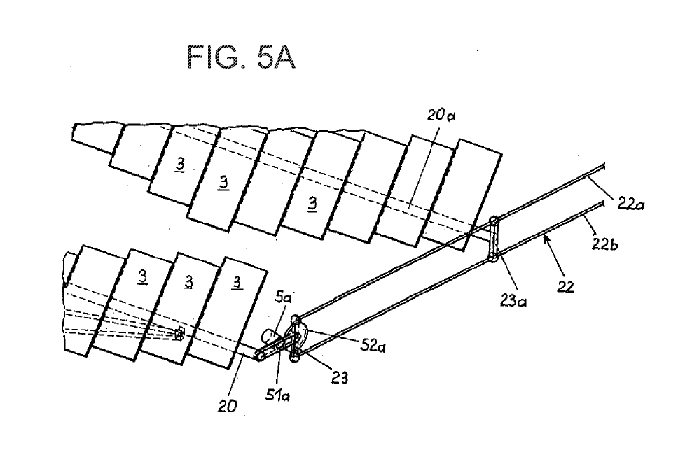

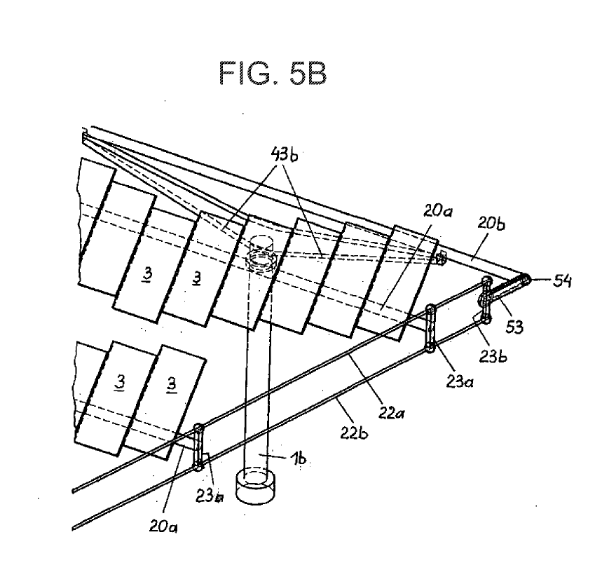

FIG. 5 shows a second exemplary embodiment of a photovoltaic system according to the invention, in an axonometric illustration, and

FIG. 5a, FIG. 5b show the details C and D of FIG. 5 on an enlarged scale in comparison with said figure.

The system for generating electrical energy by means of photovoltaic elements illustrated in FIG. 1 to FIG. 3 has two supporting columns 1 and 1b, on which a supporting framework 2 for photovoltaic elements 3 is located. The supporting framework 2 comprises a supporting cable 21 and a supporting and adjusting cable 22, which is located at a distance from said supporting cable, is aligned parallel to the supporting cable 21 and has two strands 22a and 22b, wherein supporting bars 20, 20a and 20b for the supporting framework 2 of the photovoltaic elements 3 are located between the supporting cable 21 and the supporting and adjusting cable 22, said photovoltaic elements 3 being articulated on the supporting cable 21 and on the supporting and adjusting cable 22. The supporting bar 20 and the supporting bar 20b are mounted pivotably on the supporting columns 1 and 1b, respectively, as a result of which the supporting framework 2 is supported by the supporting columns 1 and 1b. The supporting bars 20a, on the other hand, are supported by the supporting cable 21 and by the supporting and adjusting cable 22. In each case groups of a large number of photovoltaic elements 3 are fastened on the supporting bars 20 and 20a. The two strands 22a and 22b of the supporting and adjusting cable 22, said strands being arranged vertically one above the other, are connected to one another by means of transverse struts 23 and 23a, which are articulated on the two strands 22a and 22b of the supporting and adjusting cable 22, for example by means of ball joints. Those ends of the supporting bars 20 and 20a which are associated with the supporting cables 21 are mounted on the supporting cable 21 firstly such that they are capable of being pivoted about a vertical axis in each case and such that they can be rotated about the longitudinal axes of the supporting bars 20 and 20a. On the other hand, the other ends of the supporting bars 20 and 20a are rigidly connected to the transverse struts 23 and 23a, with these ends being located approximately in the center between the two strands 22a and 22b of the supporting and adjusting cable 22.

At that end of the supporting framework 2 which is associated with the supporting column b, the supporting cable 21 and the supporting and adjusting cable 22 are connected to one another by means of the bar 20b, wherein the bar 20b is articulated on a transverse strut 23b, which is located between the two strands 22a and 22b.

A first servomotor 4 is located on the supporting column 1 and can be used to pivot the supporting bar 20 about a vertical axis in a horizontal plane. Furthermore, a second servomotor 5 is located on the supporting column 1 and can be used to rotate the supporting bar 20 about its horizontally aligned axis.

By virtue of the supporting bar 20 being pivoted by means of the drive motor 4 in a horizontal plane, this movement is transferred to the supporting and adjusting cable 22 via the transverse strut 23, said supporting and adjusting cable 22 thus being moved translationally in a horizontal plane. Since this adjusting movement is transferred to the supporting bars 20a via the transverse struts 23a, all of the photovoltaic elements 3 are thus pivoted about vertical axes, as a result of which they track the east-west movement of the sun. By virtue of the second servomotor 5, the supporting bar 20 coupled thereto is rotated about its longitudinal axis. This rotary movement is transferred to both the strands 22a and 22b of the supporting and adjusting cable 22 by means of the transverse strut 23, as a result of which the two strands 20a and 22b are adjusted with respect to one another. This adjusting movement is transferred, via the transverse struts 23a, to the supporting bars 20a which are rigidly connected thereto, as a result of which the photovoltaic elements 3 fastened on said supporting bars are pivoted such that they track the solar altitude.

This shows that only a single supporting and adjusting cable 22 formed with two strands 22a and 22b is required for the two adjusting movements of the photovoltaic elements 3. Since, in addition, a large number of photovoltaic elements 3 is located on each of the supporting bars 20 and 20a, a considerable simplification of the development is thus also achieved.

As can further be seen from FIG. 3, a pinion 41 is located on the drive shaft of the motor 4, said pinion interacting with a rack 42 which is capable of rotating about a vertical axis. A two-armed adjusting bar 43 is fixedly connected to the rack 42, wherein said adjusting bar can be pivoted about the vertical axis of rotation of the rack 42 and is fixedly connected to the supporting bar 20. Since the left-hand end of the supporting bar 20 is mounted on the associated supporting cable 21 in such a way that it is capable of being pivoted about the vertical axis of rotation, as a result the supporting bar 20 can be pivoted in a horizontal plane. Since the two strands 22a and 22b are connected to the right-hand end of the supporting bar 20 by means of the transverse strut 23 in such a way as to be carried along, the transverse struts 23a are thus also moved in the horizontal direction translationally, as a result of which the supporting bars 20a fastened thereto are likewise pivoted.

As can be seen from FIG. 4, the supporting bars 20 and 20a can be in the form of latticework, which is provided at both of its ends with supporting journals 20c, which are articulated at the left-hand end on the supporting cable 21 and are connected at the right-hand end to the transverse struts 23 and 23a, whose ends are articulated on the two strands 22a and 22b of the supporting and adjusting cable 22.

FIG. 4a and FIG. 4b illustrate the precise design of the fastening of the supporting bars 20 and 20a on the supporting cable 21 and on the two strands 22a and 22b of the supporting and adjusting cable 22:

As can be seen from FIG. 4a, the left-hand end of the supporting bars 20 and 20a is formed with a sleeve 51, in which a bolt 52 is mounted, said bolt being coaxial to the supporting bars 20 and 20a. Thus, the supporting bars 20 and 20a can each be rotated about a horizontally aligned axis. The bolt 52 is connected to a vertically aligned bolt 54 by means of a bracket 53, which is curved through 90°, said bolt 54 being mounted in a sleeve 55 which is coaxial thereto. As a result, the supporting bars 20 and 20a are capable of being pivoted about a vertical axis. The sleeve 55 is clamped onto the supporting cable 21.

The right-hand end of the supporting bars 20 and 20a is in each case fixedly connected to a transverse strut 23 and 23a, with horizontally aligned sleeves 61 being fastened to the free ends of said struts. Horizontally aligned bolts 62 are mounted in these sleeves 61. Brackets 63 which are curved through 90° are fastened on the bolts 62, and vertically aligned bolts 64 are fastened at the other ends of said brackets, said bolts being mounted rotatably in sleeves 65 coaxial to said bolts. The sleeves 65 are clamped to the two strands 22a and 22b of the supporting and adjusting cable 22.

By virtue of the supporting bar 20 being pivoted in a horizontal plane, this adjusting movement is transferred to the brackets 63 via the transverse strut 23, with an adjustment in the same direction of the two strands 22a and 22b of the supporting and adjusting cable 22 being brought about by means of the bolts 64 mounted in the sleeves 65. This adjustment is transferred to the supporting bars 20a via the transverse struts 23a. By virtue of these adjusting movements, the photovoltaic elements 3 track the east-west movement of the sun. By means of the bolts 62 mounted in the sleeves 61 and the transverse strut 23, the supporting bar 20 is capable of being rotated with respect to the two strands 22a and 22b of the supporting and adjusting cable 22, wherein a rotary movement of the supporting bar 20 as a result of the transverse strut 23 being pivoted brings about an adjustment in the opposite direction of the two strands 22a and 22b, as a result of which the transverse struts 23a are also pivoted and thus the supporting bars 20a are rotated. By virtue of this adjusting movement, the photovoltaic elements 3 are pivoted and, as a result, track the solar altitude.

The second embodiment of a system according to the invention as illustrated in FIG. 5, FIG. 5a and FIG. 5b differs from the first embodiment merely by virtue of the fact that the drive motor 5a for the supporting and adjusting cable 22 is arranged on the supporting bar 20 and a rack 52a which is mounted on the supporting bar 20 is rotated via a pinion 51a, with the two strands 22a and 22b being articulated on said rack 52a. The supporting bar 20b is mounted pivotably on the supporting column 1b by means of an adjusting bar 43b. Furthermore, a guide bar 53 is articulated on the transverse strut 23b and is articulated on the supporting bar 20b via a ball joint 54.

In this exemplary embodiment, therefore, the two strands 22a and 22b of the supporting and adjusting cable 22 are adjusted with respect to one another by means of the drive motor 5a, with the transverse struts 23a being pivoted as a result of this adjusting movement, as a result of which the supporting bars 20a are rotated. As a result, the pivoting of the photovoltaic elements 3 is performed so as to adjust said photovoltaic elements to the solar altitude. The adjustment of the supporting bars 20a corresponding to the east-west movement of the sun is performed in the same way as in the first exemplary embodiment by virtue of the supporting bar 20 being pivoted, wherein this pivoting is transferred to the supporting bars 20a via the supporting and adjusting cable 22 and the transverse struts 23a, which are provided between the two strands 22a and 22b.

In addition, reference is made to the fact that the photovoltaic elements 3 which are fastened on the supporting bars 20 and 20a are adjusted vertically with respect to one another, as a result of which shadowing by other photovoltaic elements 3 is largely avoided. Reference is furthermore made to the fact that the structural configuration of such a system can also be selected such that a supporting column with servomotors is located in the central region, with the supporting framework for the photovoltaic elements extending from said supporting column towards both sides, wherein in each case a further supporting column or the like for the supporting framework is provided on both outer ends.

1-6. (canceled)

7. A system for generating electrical energy, comprising:
a supporting framework formed of supporting cables and adjusting cables;
a plurality of substantially parallel supporting bars, said supporting bars each having a substantially horizontally aligned longitudinal axis;
said supporting bars having first ends supported on a supporting cable pivotally about a substantially vertical axis and rotatably about the longitudinal axis;
said supporting bars having second ends mounted to a pivoting and rotating device formed by at least one supporting and adjusting cable; and
a multiplicity of photovoltaic elements disposed on said supporting bars and pivotable with said supporting bars about substantially vertical axes for tracking an east-west movement of the sun, and for pivoting about substantially horizontal axes with a rotation of said supporting bars about said horizontal axes, for adjustment to a solar altitude.

8. The system according to claim 7, wherein said pivoting and rotating device comprises a supporting and adjusting cable formed with two, substantially parallel strands, and wherein said supporting and adjusting cable is movable in a longitudinal direction thereof and said two strands are adjustable relative to one another.

9. The system according to claim 8, which comprises transverse struts fixedly connected to associated ends of said supporting bars and disposed between said two strands of said supporting and adjusting cable, and wherein said transverse struts are articulated on said strands.

10. The system according to claim 7, which further comprises a supporting column, a pivoting device mounted on said supporting column, and a rotating device mounted on said supporting column, and wherein at least one of said supporting bars is mounted to said supporting column to be pivoted via said pivoting device and rotated via said rotating device.

11. The system according to claim 10, wherein said supporting column has a substantially vertical longitudinal axis and said at least one of said supporting bars is rotatably mounted about said vertical longitudinal axis.

12. The system according to claim 10, wherein a pivoting movement and a rotating movement of said supporting bar is transferred to respectively other supporting bars via a longitudinal adjustment of said supporting and adjusting cable that is coupled to said supporting bar, and via an adjustment in an opposite direction of said two strands of said supporting and adjusting cable.

13. The system according to claim 7, wherein a pivoting movement and a rotating movement of said supporting bar is transferred to respectively other supporting bars via a longitudinal adjustment of said supporting and adjusting cable that is coupled to said supporting bar, and via an adjustment in an opposite direction of said two strands of said supporting and adjusting cable.

14. The system according to claim 7, which comprises:
one supporting column at each end of said supporting framework, each of said supporting columns supporting a respective supporting bar pivotally and rotatably;
drive assemblies mounted to at least one of said supporting columns for pivoting and for rotating the associated said supporting bar;
wherein remaining said supporting bars with said photovoltaic elements are mounted at said first ends on a supporting cable for pivoting about a substantially vertical axis and rotating about said longitudinal axis; and
said supporting bars are coupled to one another by way of said supporting and adjusting cable at said second ends so as to enable pivoting in a substantially horizontal plane and rotation about said longitudinal axis.

15. A system for generating electrical energy, comprising:
at least one supporting column having a substantially vertical longitudinal axis;
a supporting framework formed of supporting cables and adjusting cables;
a plurality of substantially parallel supporting bars, said supporting bars each having a substantially horizontally aligned longitudinal axis;
said supporting bars having first ends supported on a supporting cable pivotally about a substantially vertical axis and rotatably about the longitudinal axis;
said supporting bars having second ends mounted to a pivoting and rotating device formed by at least one supporting and adjusting cable;
said supporting bars including at least one supporting bar rotatably mounted on said at least one supporting column about said longitudinal axis;
a pivoting device mounted to said supporting column and configured for pivoting said at least one supporting bar, and a rotating device mounted to said supporting column for rotating said at least one supporting bar; and
a multiplicity of photovoltaic elements disposed on said supporting bars and pivotable with said supporting bars about substantially vertical axes for tracking an east-west movement of the sun, and for pivoting about substantially horizontal axes with a rotation of said supporting bars about said horizontal axes, for adjustment to a solar altitude.
